(19) United States
(12) Patent Application Publication
(10) Pub. No.: US 2026/0304805 A1
(43) Pub. Date: Oct. 1, 2026

(54) SEMICONDUCTOR STRUCTURE AND METHOD OF MANUFACTURING THE SAME

(71) Applicant: Winbond Electronics Corp., Taichung City (TW)

(72) Inventor: Kai-Ping CHEN, Taichung City (TW)

(21) Appl. No.: 19/634,494

(22) Filed: Mar. 31, 2026

(30) Foreign Application Priority Data
Mar. 31, 2025 (TW) 114112230

(51) Int. Cl. H10D 1/68; H10D 1/00

(52) U.S. Cl. CPC H10D 1/716; H10D 1/043; H10D 1/714

(57) ABSTRACT

A semiconductor structure includes a substrate, a plurality of columnar supporters, and a plurality of capacitor structures. The columnar supporters are disposed over the substrate. The outer sidewall of each of the columnar supporters includes a plurality of supporting portions and a plurality of connecting portions. The capacitor structures are disposed on the supporting portions of the outer sidewalls of each of the columnar supporters, and the connecting portions connect the capacitor structures.

### CROSS REFERENCE TO RELATED APPLICATIONS

This Application claims priority of Taiwan Patent Application No. 114112230, filed on Mar. 31, 2025, the entirety of which is incorporated by reference herein.

### BACKGROUND OF THE INVENTION

### Field of the Invention

The present invention relates to a semiconductor structure with storage capacitors and a method for manufacturing the same, and in particular, it relates to a semiconductor structure capable of stably supporting a storage capacitor and enhancing electrical performance, and a method for manufacturing the same.

### Description of the Related Art

Currently, many of the developments in semiconductor manufacturing are targeted towards the miniaturization of components. This is accompanied by many challenges. For example, a columnar capacitor structure typically includes a bottom electrode having a U-shaped cross-section, a top electrode, and a dielectric layer disposed between the bottom electrode and the top electrode. One or more support planes may be provided to support the top portion, and/or middle portion, and/or the bottom portion of the capacitor structure. However, with continued scaling down of the device size, the aspect ratio of the capacitor structure increases, rendering the structure more susceptible to collapse and thus hindering yield improvement. In addition, as the unit storage capacitance decreases with continued scaling down, it becomes necessary to increase the refresh frequency or otherwise accept reduced reliability, thereby degrading the quality of DRAMs including such columnar capacitor structures.

### BRIEF SUMMARY OF THE INVENTION

Some embodiments of the present disclosure provide a semiconductor structure, including: a substrate; a plurality of columnar supporters disposed over the substrate, the outer wall of each of the columnar supporters including a plurality of supporting portions and a plurality of connecting portions; and a plurality of capacitor structures disposed on the supporting portions of the outer wall of each of the columnar supporters, and the connecting portions connecting the capacitor structures.

Some embodiments of the present disclosure provide a method of manufacturing the semiconductor structure, including: forming a plurality of columnar supporters over the substrate, the outer sidewall of each of the columnar supporters includes a plurality of supporting portions and a plurality of connecting portions; and forming a plurality of capacitor structures on the supporting portion of the outer sidewall of each of the columnar supporters.

The disclosed semiconductor structure and manufacturing method increase the capacitor's aspect ratio and capacitance, enhance stability, boost yield, and improve the device's electrical performance.

### BRIEF DESCRIPTION OF THE FIGURES

FIGS. 1A-7A are perspective views of a semiconductor structure at various intermediate manufacturing stages according to some embodiments of the present disclosure.

FIGS. 1B-7B respectively show schematic cross-sectional views taken along line B-B′ in FIGS. 1A-7A.

FIGS. 8A-8D are schematic diagrams illustrating a supporter of a semiconductor structure at multiple intermediate manufacturing stages according to some other embodiments of the present disclosure.

FIG. 9A is a perspective view of a semiconductor structure at an intermediate manufacturing stage according to some embodiments of the present disclosure.

FIG. 9B is a schematic cross-sectional view taken along line 9B-9B′ in FIG. 9A.

FIG. 9C is a schematic cross-sectional view of a supporter and a capacitor structure of a semiconductor structure according to some other embodiments of the present disclosure (e.g., taken along line 9B-9B′ of FIG. 9A).

FIGS. 10A and 10B are schematic cross-sectional views of a semiconductor structure at an intermediate manufacturing stage according to some embodiments of the present disclosure.

FIG. 11 is a perspective view of a semiconductor structure including a capacitor structure according to some embodiments of the present disclosure.

### DETAILED DESCRIPTION OF THE INVENTION

The following content provides many different embodiments for implementing different features of the embodiments of the present invention. These are merely examples and are not intended to limit the present invention. In addition, the formation of a first feature over or on a second feature in the description that follows may include embodiments in which the first and second features are formed in direct contact, and may also include embodiments in which the first and second features may not be in direct contact, unless otherwise specifically excluded. For simplicity and clarity, the embodiments of the present disclosure may use the same or similar reference numerals and/or letters for the same or similar features in different embodiments, and may only show a portion of the semiconductor structure related to the present invention. Furthermore, there may be additional steps before, during, or after each step of the manufacturing method to form other required components/ layers, and some steps may be replaced or deleted in other embodiments.

The capacitor structure proposed in the embodiments of the present disclosure may be used independently or applied in a semiconductor device. For example, it may be applied in a dynamic random access memory (DRAM) device, which includes related components such as bit lines, storage node contacts, word lines, and peripheral circuits. However, other suitable types of memory or electronic devices may also be applied in the embodiments of the present disclosure, and the present disclosure is not limited thereto.

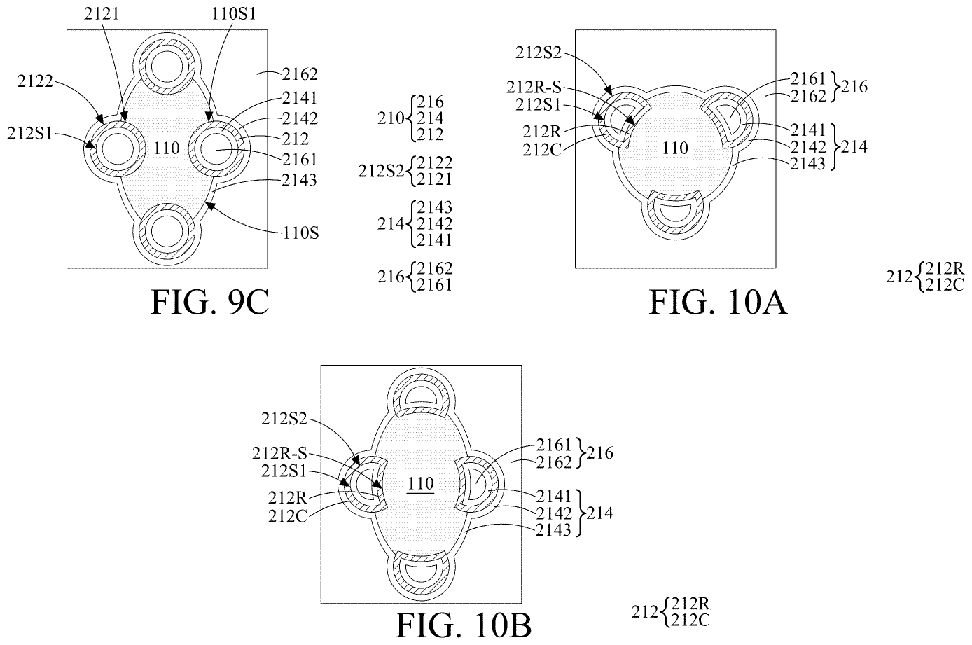

As shown in FIG. 9A, according to an embodiment of the present disclosure, the semiconductor structure 2 includes a plurality of solid columnar supporters 110 disposed over the substrate 100, and a plurality of capacitor structures 210 formed on the outer sidewalls 110S of each columnar supporter 110. In this example, three capacitor structures 210 are adjacent and substantially equidistantly disposed on the outer sidewalls 110S of each columnar supporter 110, but the present invention is not limited thereto.

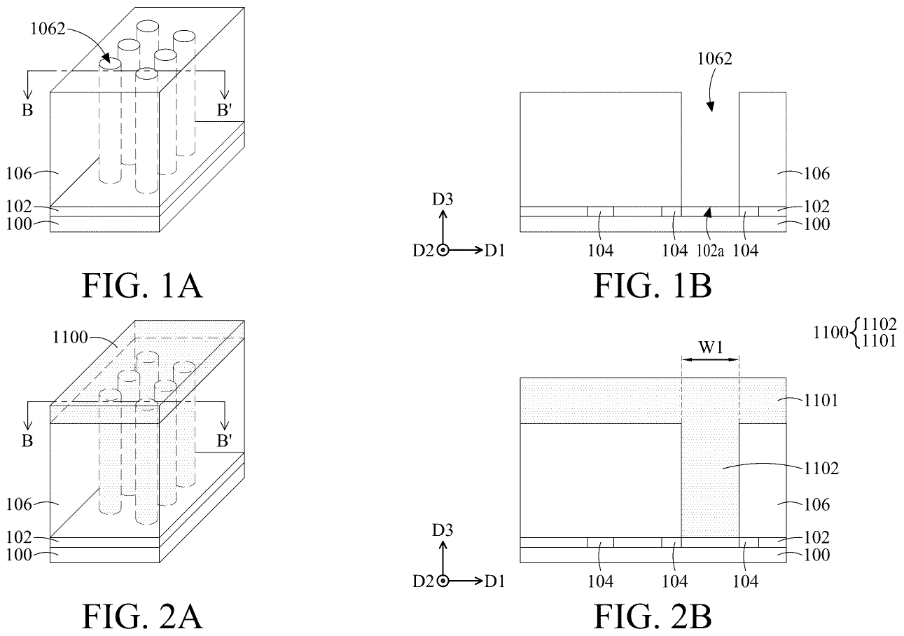

Referring to FIGS. 1A, 1B, 2A, 2B, 3A, and 3B, a sacrificial material layer 106 having a plurality of embedded supporting pillars 1102 may be formed over the substrate 100, wherein the supporting pillars 1102 are spaced apart from one another, as described in detail hereinafter.

Referring to FIGS. 1A and 1B, an insulating layer 102 and a sacrificial material layer 106 may be sequentially formed on a substrate 100. The material of the substrate 100 may include a semiconductor material, such as silicon, gallium arsenide, gallium nitride, germanium silicide, other suitable substrate materials, or a combination thereof. In some embodiments, the substrate 100 is silicon-on-insulator (SOI). In some embodiments, a storage node contact 104 may be formed in the insulating layer 102 to electrically connect the substrate 100 to a capacitor structure to be formed subsequently.

The sacrificial material layer 106 has a plurality of supporting holes 1062. The position of each of the supporting holes 1062 is, for example, between the capacitor structures that are subsequently formed. As shown in FIG. 1B, the supporting holes 1062 may expose the top surface 102a of the insulating layer 102 between adjacent storage node contacts 104. In this embodiment, the supporting holes 1062 may be formed such that the adjacent storage node contacts 104 are not exposed. However, in other examples, the supporting hole 1062 not only exposes the insulating layer 102, but also exposes a portion of the adjacent storage node contact 104.

Furthermore, the plane in which the top surface of the substrate 100 lies is, for example, defined by a first direction D1 and a second direction D2, and is hereinafter referred to as the D1-D2 plane. According to the embodiment, the supporting holes 1062 are perpendicular to the plane in which the top surface of the substrate 100 lies (i.e., the D1-D2 plane), and extend, for example, along a third direction D3. The supporting holes 1062 are spaced apart from one another.

Thereafter, referring to FIGS. 2A and 2B, according to some embodiments, a supporting material 1100 is excessively deposited over the sacrificial material layer 106 to fill the supporting holes 1062. Therefore, the supporting material 1100 includes an excess portion 1101 over the sacrificial material layer 106 and supporting pillars 1102 in the supporting holes 1062.

According to some embodiments, the sacrificial material layer 106 includes an insulating material having an etching selectivity with the supporting material 1100, such as, but not limited to, oxide materials. The supporting material 1100 includes an insulating material with sufficient supporting strength. In some embodiments, the supporting material 1100 includes silicon nitride (SiN), silicon monoxide (SiO), silicon carbonitride (SiCN), or a combination thereof.

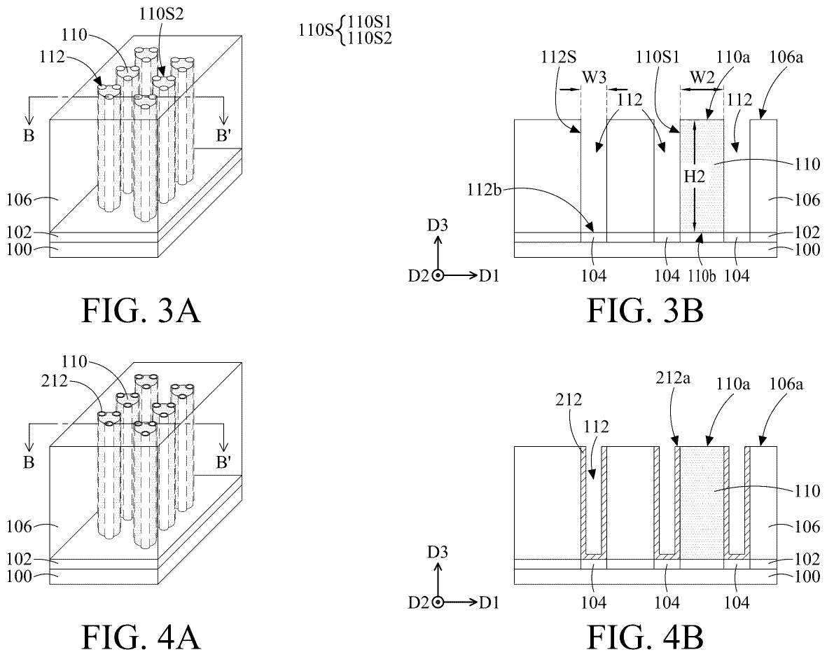

Next, referring to FIGS. 3A and 3B, the excess portion 1101 of the supporting material 1100 is removed. The excess portion 1101 of the supporting material 1100 may be removed by a planarization process, such as a chemical mechanical polishing (CMP) process, a mechanical polishing process, a recess etching process, or a combination thereof, until a top surface 106a of the sacrificial material layer 106 is exposed.

Thereafter, according to some embodiments, a plurality of capacitor structures accommodating holes 112 are formed on the sidewall edge of each supporting pillar 1102. The longitudinal direction (e.g., along the third direction D3) of each of the capacitor structure accommodating hole 112 may be perpendicular to the substrate 100 (e.g., D1-D2 plane). Each of the capacitor structure accommodating hole 112 exposes a corresponding storage node contact 104.

In some embodiments, during the formation of the capacitor structures accommodating holes 112, the supporting pillars 1102 may also be partially removed, thereby forming smaller columnar supporters 110. For example, the size of the columnar supporter 110 (e.g., the width W2 in the first direction D1) may be smaller than the size of the supporting pillars 1102 (e.g., the width W1 in the first direction D1). According to this embodiment, the cross-section of the columnar supporter 110 may have a concave-convex profile.

Furthermore, in some embodiments, the outer sidewall 110S of the columnar supporter 110 includes a plurality of supporting portions 110S1 and a plurality of connecting portions 110S2. Each of the capacitor structure accommodating holes 112 exposes the supporting portion 110S1 of the outer sidewall 110S of the adjacent columnar supporter 110. These connecting portions 110S2 are connected to the capacitor structure accommodating holes 112. According to the example, the vertical height of the supporting portion 110S1 (i.e., the depth of the capacitor structure accommodating hole 112) is equal to the vertical height H2 of the columnar supporter 110. Accordingly, the vertical height H2 of the columnar supporter 110 in the present embodiment may be used to control the depth of the capacitor structure accommodating hole 112, thereby facilitating an increase in the height of the subsequently formed capacitor structure, which is proportional to the unit storage capacitance. In the present embodiment, in order for the columnar supporter 110 to provide sufficient support for the capacitor structure, the vertical height (e.g., H2) of the supporting portion 110S1 of the columnar supporter 110 is greater than the width W2 of the columnar supporter 110.

Thereafter, referring to FIGS. 4A and 4B, according to some embodiments, a bottom electrode 212 is formed on the surface of the capacitor structure accommodating hole 112. The bottom electrode 212 may be formed on the sacrificial material layer 106 by a chemical vapor deposition process, an atomic layer deposition process, a physical vapor deposition process, other suitable processes, or a combination thereof.

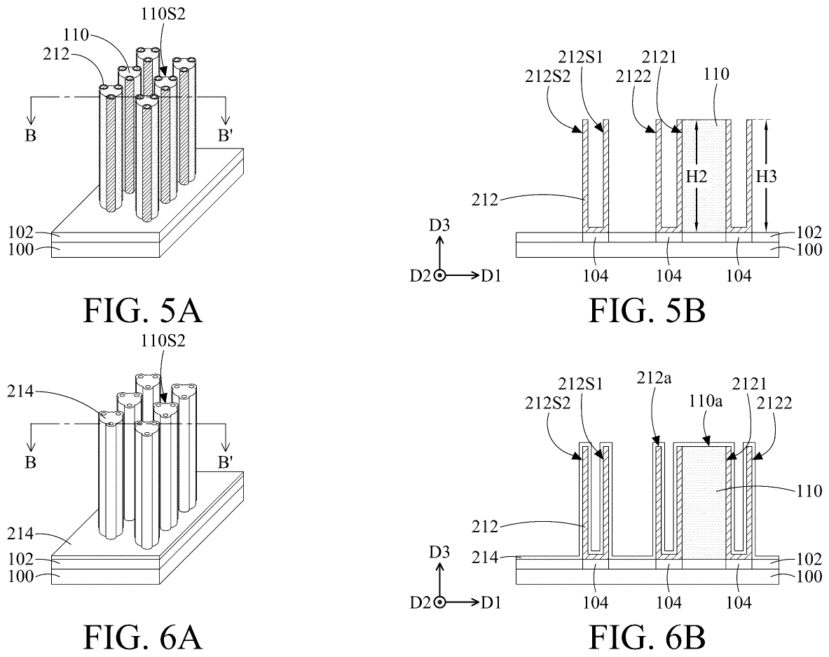

In some embodiments, the top surface 212a of the bottom electrode 212 is leveled with the top surface 110a of the columnar supporter 110. The bottom electrode 212 has a U-shaped cross-section in the capacitor structure accommodating hole 112. The outer sidewall of the bottom electrode 212 may include a supported portion 2121 (as indicated in FIG. 5B) that is in direct contact with the supporting portion 110S1 of the columnar supporter 110, and the height of the supported portion 2121 (i.e., H3 in FIG. 5B) is greater than the width W2 of the columnar supporter 110, thereby preventing collapse of the bottom electrode 212.

Thereafter, referring to FIGS. 5A and 5B, according to some embodiments, the sacrificial material layer 106 is removed. For example, the sacrificial material layer 106 may be removed by a wet etching process, which may substantially leave other components, such as the insulating layer 102, the columnar supporter 110, and the bottom electrode 212, un-damaged.

According to the above-described embodiment, the bottom electrode 212 of the capacitor structure is formed after the formation of the columnar supporter 110. Compared to conventional approaches that employ horizontal supporting layers—which are prone to issues such as collapse of the capacitor structure, short circuits, and/or degraded quality—the above-described embodiment enables each bottom electrode 212 to be stably supported by the solid columnar supporter 110. As a result, the vertical height H3 of the bottom electrode 212 may be increased along with the vertical height H2 of the columnar supporter 110, thereby facilitating an increase in unit storage capacitance and improved scalability, while also addressing the aforementioned issues associated with conventional structures. In one embodiment, the ratio of the vertical height H3 of the bottom electrode 212 to the vertical height H2 of the columnar supporter 110 ranges from 0.7 to 1.3.

Thereafter, referring to FIGS. 6A and 6B, according to some embodiments, a dielectric layer 214 is formed on the substrate 100 and on the bottom electrode 212. For example, a dielectric material having a dielectric constant greater than or equal to 3.9 is conformally deposited to cover the top surface 102a of the insulating layer 102, the surface of the bottom electrode 212, and the top surface 110a of the columnar supporter 110 and the connecting portion 110S2 of the outer sidewall 110S. More specifically, the dielectric layer 214 covers the remaining portion 2122 of the outer sidewall 212S2 of the bottom electrode 212 except for the supported portion 2121.

In some embodiments, the dielectric layer 214 may be formed by a vapor deposition process. The dielectric layer 214 includes, for example, aluminum oxide (AlO), yttrium oxide (Y₂O₃), titanium oxide (TiO), niobium oxide (NbO), hafnium oxide (HfO), lanthanum oxide (LaO), lanthanum aluminate (LaAlO), zirconium oxide (ZrO), silicon monoxide (SiO), silicon nitride (SiN), hafnium oxide silicate (HfSiO), hafnium oxide silicate nitride (HfSiON), zirconium oxide silicate (ZrSiO), hafnium zirconate (HfZrO) or other suitable dielectric materials for storing charge. The dielectric layer 214 and the columnar supporter 110 are made of different materials. In one embodiment, the dielectric constant of the dielectric layer 214 is greater than the dielectric constant of the columnar supporter 110. The dielectric layer 214 may be a single layer or a multi-layer structure, such as but not limited to a two-layer structure of silicon dioxide layer/silicon nitride layer.

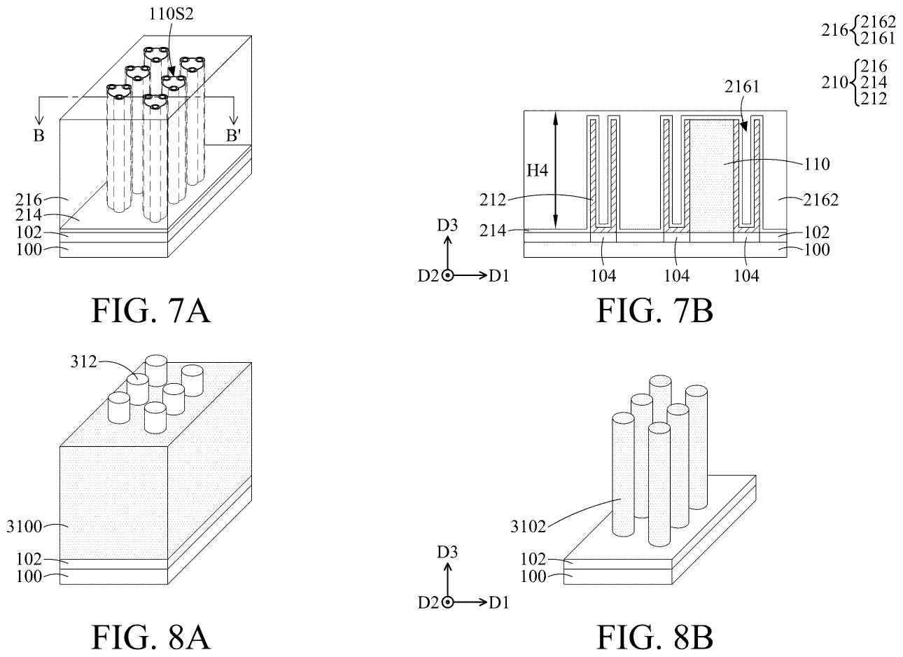

Thereafter, referring to FIGS. 7A and 7B, a top electrode 216 is formed over the dielectric layer 214. The top electrode 216 may include a first portion 2161 on the inner side of the bottom electrode 212 and a second portion 2162 on the outer side of the bottom electrode 212. In other words, the first portion 2161 of the top electrode 216 is in the capacitor structure accommodating hole 112. The top electrode 216, the dielectric layer 214 and the bottom electrode 212 form a capacitor structure 210, and charges may be stored in the dielectric layer 214. The ratio of the maximum vertical height H4 of the top electrode 216 to the vertical height H2 of the columnar supporter 110 may range from 0.6 to 1.5, so as to reduce the resistance value. The second portion 2162 of the top electrode 216 may have a maximum vertical height H4. The top electrode 216 and the bottom electrode 212 may each include titanium nitride, titanium oxynitride, titanium silicon nitride, tantalum, tantalum nitride, tungsten nitride, silicon germanium, silicon boron, other suitable conductive materials, or combinations thereof. In some embodiments, the top electrode 216 and the bottom electrode 212 may include the same material (e.g., titanium nitride). However, in other embodiments, the top electrode 216 and the bottom electrode 212 may also include different materials.

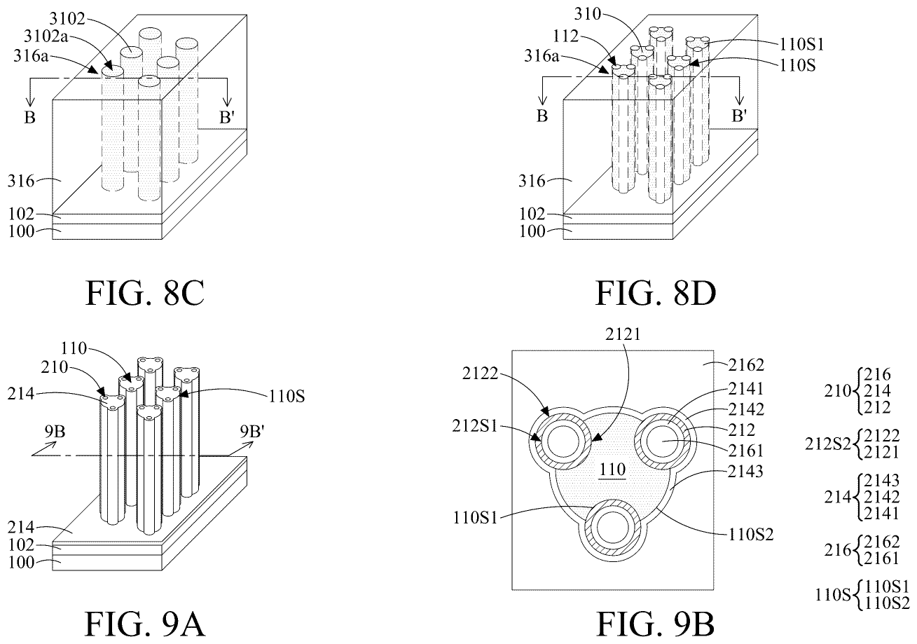

The above-mentioned embodiment forms the supporter by etching a supporting hole in the sacrificial material layer and then filling the supporting hole with a supporting material, but the present invention is not limited thereto. As shown in FIGS. 8A-8D, another method for manufacturing the supporter of the present invention is illustrated.

Referring to FIG. 8A, a supporting material 3100 is formed on the insulating layer 102 and the storage node contact 104. The thickness of the supporting material 3100 is determined according to the height of the support to be formed. A mask 312 is formed on the supporting material 3100 to define a support. The material of the supporting material 3100, the configuration, material, and manufacturing method of the substrate 100, the insulating layer 102, and the storage node contact 104 may refer to the foregoing embodiments and will not be repeated here.

Referring to FIG. 8B, the supporting material 3100 is patterned according to the mask 312 to form supporting pillars 3102. After forming the supporting pillars 3102, the mask 312 may be removed by a known process, such as an ashing process.

Thereafter, referring to FIG. 8C, a sacrificial material layer 316 is formed to cover the supporting pillars 3102, the insulating layer 102, and the storage node contacts 104. The method for forming the sacrificial material layer 316 may include excessively depositing a sacrificial material, followed by a planarization process, such as a chemical mechanical polishing (CMP) process, a mechanical polishing process, a etch-back process, or a combination thereof, until a top surface 3102a of the supporting pillars 3102 is exposed, thereby forming the sacrificial material layer 316 with a top surface 316a that is substantially coplanar with the top surface 3102a of the supporting pillars 3102. At this stage of the process, a sacrificial material layer 316 having a plurality of embedded supporting pillars 3102 may be formed over the substrate 100, wherein the supporting pillars 3102 are spaced apart from one another.

Thereafter, referring to FIG. 8D, a plurality of capacitor structures accommodating holes 112 are formed at the sidewall edges of the respective supporting pillars 3102. For example, one or more etching processes may be performed to remove portions of the sacrificial material layer 316 and portions of the supporting pillars 3102, thereby forming the capacitor structures accommodating holes 112. The remaining portion of the supporting pillar 3102 forms the supporter 310, wherein each of the capacitor structure accommodating hole 112 exposes the supporting portion 110S1 of the outer sidewall 110S of the adjacent supporter 310. Other details may be referred to the foregoing embodiments and will not be elaborated here.

After the supporter 310 and the capacitor structure accommodating hole 112 are formed, the subsequent components may be manufactured by referring to the contents of FIGS. 4A, 4B, 5A, 5B, 6A, 6B, 7A, and 7B. For example, a bottom electrode 212 with a U-shaped cross-section is formed in the capacitor structure accommodating hole 112, the sacrificial material layer 316 is removed, a dielectric layer 214 is conformally deposited on the bottom electrode 212, and a top electrode 216 is formed on the dielectric layer 214 to complete the capacitor structure 210 as shown in FIGS. 7A and 7B.

The semiconductor structure 2 of the present embodiment may have the following features. According to the present embodiment, as shown in FIG. 9A, a plurality of columnar supporters 110 are disposed over the substrate 100, each columnar supporter 110 may be a solid insulating pillar, a plurality of (e.g., three) capacitor structures 210 are formed on the outer sidewall 110S of the columnar supporter 110, and the longitudinal direction of the capacitor structure 210 may be substantially parallel to the longitudinal direction of the columnar supporter 110. For clarity in illustrating the relationship between the columnar supporter 110 and the capacitor structure 210 of the embodiment, FIG. 9A is simplified to represent the capacitor structure 210 with a single-layer pillar, and the second portion 2162 of the top electrode 216 outside the bottom electrode 212 and the dielectric layer 214 is omitted.

Furthermore, as shown in FIG. 9B, in some embodiments, the supporting portion 110S1 of the outer sidewall 110S of the columnar supporter 110 is covered by the adjacent bottom electrode 212, and the connecting portion 110S2 of the outer sidewall 110S is covered by the dielectric layer 214. In a cross-section, the dielectric layer 214 of these capacitor structures 210 may surround the bottom electrode 212 and the columnar supporter 110 in a closed configuration. More specifically, the dielectric layer 214 may include a first portion 2141, a second portion 2142, and a third portion 2143. The first portion 2141 is disposed on an inner sidewall 212S1 of the bottom electrode 212, the second portion 2142 covers the remaining portion 2122 of an outer sidewall 212S2 of the bottom electrode 212 that protrudes beyond the columnar supporter 110, and the third portion 2143 covers a connecting portion 110S2 of an outer sidewall 110S of the columnar supporter 110.

Although the above embodiment illustrates each columnar supporter 110 supporting three capacitor structures 210 as an example, the present disclosure is not limited thereto. Furthermore, different columnar supporters 110 may also be configured with different numbers of capacitor structures, depending on the design requirements, such as the size and spacing of the capacitor structure in the actual application. According to other embodiments of the present invention, such as FIG. 9C, four capacitor structures may be configured on the outer sidewall of a columnar supporter 110. For the purpose of simplicity, the configuration, materials, and processes of these components may refer to the contents of the foregoing embodiments and will not be repeated here.

Furthermore, the top-view shapes of the capacitor structure and the supporter of the embodiment are not particularly limited, for example, they may have a substantially circular, elliptical, diamond, or other regular or irregular top-view shapes. The shape of the bottom electrode 212 in the capacitor structure 210 is related to the shape of the capacitor structure accommodating hole 112 (FIGS. 3A, 3B, and 8B), and thus affects the top-view shapes of other material layers, such as the first portion 2141 of the dielectric layer 214 and the first portion 2161 of the top electrode 216. The following examples illustrate several possible variations, but the present invention is not limited thereto.

According to some embodiments, as shown in FIG. 9C, the bottom electrode 212 has a circular shape, and the supporting portion 110S1 of the outer sidewall 110S of the columnar supporter 110 is concave, such that the portion of the capacitor structure 210 in contact with the columnar supporter 110 is embedded within the columnar supporter 110. However, the present invention does not limit the shape of the supporting portion 110S1 of the outer sidewall 110S of the columnar supporter 110 or the bottom electrode 212.

As shown in FIGS. 10A and 10B, the bottom electrode 212 of each capacitor structure 210 includes a concave portion 212R and a convex portion 212C. The concave portion 212R is concave in the direction away from the columnar supporter 110, wherein the outer sidewall 212R-S of the concave portion 212R is in direct contact with the supporting portion 110S1 of the outer sidewall 110S of the columnar supporter 110. The convex portion 212C is connected to the concave portion 212R. A portion of the convex portion 212C and the concave portion 212R may be embedded in the columnar supporter 110, and the remaining portion of the convex portion 212C may protrude outside the columnar supporter 110. In addition, the columnar supporter 110 may have a cross-sectional profile that is substantially circular (FIG. 10A) or elliptical (FIG. 10B), but the present invention is not limited thereto.

In addition, the capacitor structure 210 proposed in the embodiment may be applied in a semiconductor device in combination with other types of capacitor structures to form a hybrid capacitor component.

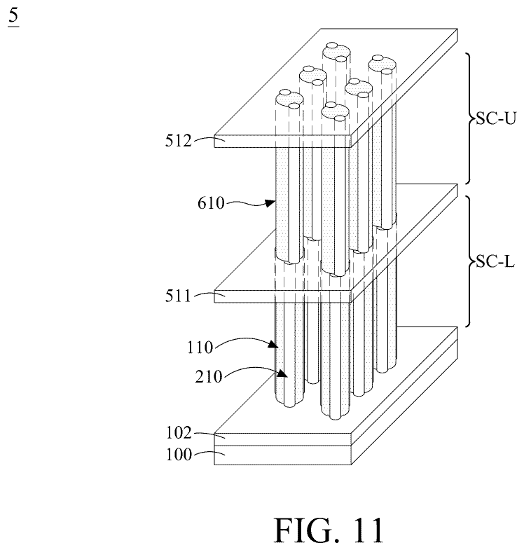

As shown in FIG. 11, the semiconductor structure 5, having a hybrid capacitor component, includes upper and lower layers of capacitors. In this example, the lower capacitor SC-L may include the capacitor structure 210 of the embodiment, which includes a plurality of solid vertical columnar supporters 110 disposed on the insulating layer 102. The upper capacitor SC-U may include a conventional capacitor structure 610, which is supported by two horizontal supporters. In this example, the horizontal supporter 511 is disposed over the capacitor structure 210 and the solid vertical columnar supporter 110. The capacitor structure 610 is disposed over the capacitor structure 210, and a bottom portion of the capacitor structure 610 is embedded in the horizontal supporter 511 and electrically connected to the corresponding underlying capacitor structure 210. The horizontal supporter 512 is disposed over the horizontal supporter 511, and an upper portion of the capacitor structure 610 is embedded in the horizontal supporter 512. The horizontal support members 511 and 512 limit the bottom and top of the capacitor structure 610 to prevent the capacitor structure 610 from bending or collapsing, respectively. The insulating layer 102, the columnar supporter 110, and the horizontal supporters 511 and 512 may be, for example, but not limited to, silicon nitride layers or other suitable dielectric layers capable of providing mechanical support. The capacitor structure 610 and the horizontal supporters 511 and 512 may be manufactured using any known structures and fabrication processes, and thus will not be described in detail herein. According to the semiconductor structure 5 having a hybrid capacitor component in the present embodiment, the aspect ratio of the supporting holes 1062 may be reduced, thereby enabling a balance between yield and scaling requirements in certain applications.

In the above-mentioned embodiment, a plurality of storage node contacts 104 are formed in the insulating layer 102, and these storage node contacts 104 are electrically connected to different capacitor structures respectively, but the present invention is not limited thereto. For example, in other embodiments not shown, a conductive line may be formed in the insulating layer 102 and electrically connected to multiple capacitor structures, thereby enabling application in semiconductor devices requiring high capacitance.

Based on the above, the semiconductor structure and the manufacturing method thereof proposed in some embodiments of the present disclosure have many advantages. In the semiconductor structure according to the embodiments, whether applied independently or in combination with other conventional capacitor structures, the bottom electrode of the capacitor structure may attain an increased height by being supported by the solid supporter. In addition to increasing capacitance, the resulting capacitor structure exhibits high structural stability, which may prevent bending or collapse of the capacitor structure, thereby enhancing product yield. Therefore, compared to conventional capacitor structures, the capacitor structure of the embodiments may have a greater aspect ratio and capacitance under the same capacitor structure width, which is advantageous for the scaling of capacitor structures and the improvement of product quality. Furthermore, in each of the capacitor structures, only a portion of the outer sidewall of the bottom electrode is formed on the supporter, and the bottom electrode, dielectric layer, and top electrode of the capacitor structure may still form a double-sided capacitor configuration. Specifically, the capacitor structure may include a five-layer arrangement from the inside to the outside, sequentially including: a top electrode material, a high-k dielectric material, a bottom electrode material, another high-k dielectric material, and another top electrode material. Therefore, in the scaling of capacitor structures, the supporters disposed between multiple capacitor structures do not interfere with the multilayer configuration of the capacitor structures, and the charge storage capability is not compromised or diminished by the inclusion of the supporters in the embodiments.

In view of the foregoing, the capacitor structure of the embodiments exhibits structural stability, which may improve product yield, reduce waste during the manufacturing process, and provide higher capacitance to enhance performance. For example, when applied in a DRAM device, the capacitor structure may reduce the memory data refresh frequency, thereby lowering the overall power consumption of the memory. Therefore, the present invention provides a green semiconductor technology.

What is claimed is:

1. A semiconductor structure, comprising:
a substrate;
a plurality of columnar supporters disposed over the substrate, wherein outer sidewalls of each of the columnar supporters comprise a plurality of supporting portions and a plurality of connecting portions; and
a plurality of capacitor structures disposed on the supporting portions of the outer sidewalls of each of the columnar supporters, and the connecting portions connect the capacitor structures.

2. The semiconductor structure as claimed in claim 1, wherein each of the columnar supporters is a solid insulating pillar, and a longitudinal direction of each of the columnar supporters is parallel to a longitudinal direction of each of the capacitor structures.

3. The semiconductor structure as claimed in claim 1, wherein each of the capacitor structures comprises a bottom electrode, a dielectric layer, and a top electrode, wherein outer sidewalls of the bottom electrode have a supported portion in direct contact with the supporting portions, and wherein the dielectric layer covers a remaining portion of the outer sidewall of the bottom electrode other than the supported portion.

4. The semiconductor structure as claimed in claim 1, wherein the supporting portions of the outer sidewalls of each of the columnar supporters are concave, such that portions of each of the capacitor structures in contact with the columnar supporters are embedded in the columnar supporters.

5. The semiconductor structure as claimed in claim 1, wherein each of the capacitor structures comprises a bottom electrode, a dielectric layer, and a top electrode, wherein a first portion of the dielectric layer is on inner sidewalls of the bottom electrode, and wherein a second portion of the dielectric layer covers a remaining portion of the outer sidewalls of the bottom electrode protruding outside the columnar supporters, and wherein a third portion of the dielectric layer covers the connecting portions of the outer sidewalls of the columnar supporters.

6. The semiconductor structure as claimed in claim 1, wherein a cross-sectional view of the columnar supporters has a concave-convex profile.

7. The semiconductor structure as claimed in claim 1, wherein a ratio of vertical height of bottom electrodes of the capacitor structures to vertical height of the columnar supporters ranges from 0.7 to 1.3.

8. The semiconductor structure as claimed in claim 1, wherein a ratio of maximum vertical height of top electrodes of the capacitor structures to a vertical height of the columnar supporters ranges from 0.6 to 1.5.

9. The semiconductor structure as claimed in claim 1, wherein in a cross-sectional view, dielectric layers of the capacitor structures enclose bottom electrodes of the capacitor structures and each of the columnar supporters.

10. The semiconductor structure as claimed in claim 1, wherein a bottom electrode of each of the capacitor structures comprises a concave portion concave in a direction away from the columnar supporters, wherein an outer sidewall of the concave portion is in direct contact with the columnar supporters.

11. The semiconductor structure as claimed in claim 10, wherein the bottom electrode further comprises a convex portion connected to the concave portion, and wherein a portion of the convex portion and the concave portion are embedded in the columnar supporters, and a remaining portion of the concave portion protrudes outside the columnar supporters.

12. The semiconductor structure as claimed in claim 1, further comprising:
a first horizontal supporter over the capacitor structures and the columnar supporters;
a plurality of second capacitor structures over the capacitor structures and electrically connected to the corresponding capacitor structures, wherein bottom portions of the second capacitor structures are embedded in the first horizontal supporter; and
a second horizontal supporter, wherein top portions of the second capacitor structures are embedded in the second horizontal supporter.

13. The semiconductor structure as claimed in claim 1, further comprising:
an insulating layer between the substrate and the capacitor structures; and
a plurality of storage node contacts in the insulating layer and electrically connected to the respective ones of the capacitor structures.

14. A method of manufacturing a semiconductor structure, comprising:
forming a plurality of columnar supporters on a substrate, wherein outer sidewalls of each of the columnar supporters comprise a plurality of supporting portions and a plurality of connecting portions; and
forming a plurality of capacitor structures on the supporting portions of the outer sidewalls of each of the columnar supporters, wherein the connecting portions connect the capacitor structures.

15. The method of manufacturing the semiconductor structure as claimed in claim 14, further comprising:
embedding a plurality of supporting pillars in a sacrificial material layer over the substrate, wherein the supporting pillars are spaced apart from each other;
removing a portion of the sacrificial material layer and a portion of the supporting pillars to form a plurality of capacitor structure accommodating holes, wherein a remaining portion of the supporting pillars form the columnar supporters, and wherein the capacitor structure accommodating holes expose the supporting portions of the outer sidewalls of each of the columnar supporters;
forming a bottom electrode in each of the capacitor structure accommodating holes;
removing the sacrificial material layer;
conformally depositing a dielectric layer on the bottom electrode; and
forming a top electrode on the dielectric layer.

16. The method of manufacturing the semiconductor structure as claimed in claim 15, wherein embedding the supporting pillars in the sacrificial material layer comprises:
forming the sacrificial material layer over the substrate;
forming a plurality of supporting holes in the sacrificial material layer; and
filling the supporting holes with a supporting material to form the supporting pillars in the supporting holes.

17. The method of manufacturing the semiconductor structure as claimed in claim 15, wherein embedding the supporting pillars in the sacrificial material layer comprises:
forming a supporting material over the substrate;
forming a mask on the supporting material to define the columnar supporters;
patterning the supporting material according to the mask to form the supporting pillars;
removing the mask;
forming the sacrificial material layer covering the supporting pillars, wherein a top surface of the sacrificial material layer is coplanar with top surfaces of the supporting pillars.

18. The method of manufacturing the semiconductor structure as claimed in claim 15, wherein the bottom electrode of each of the capacitor structures comprises a concave portion concave in a direction away from the columnar supporters, wherein an outer sidewall of the concave portion is in direct contact with the columnar supporters.

19. The method of manufacturing the semiconductor structure as claimed in claim 18, wherein each of the capacitor structures comprises a bottom electrode, a dielectric layer, and a top electrode, wherein outer sidewalls of the bottom electrode have a supported portion in direct contact with the supporting portions, and the dielectric layer covers a remaining portion of the outer sidewalls of the bottom electrode other than the supported portion.

20. The method of manufacturing the semiconductor structure as claimed in claim 18, wherein the supporting portion of the outer sidewalls of each of the columnar supporters is concave, such that a portion of each of the capacitor structures in contact with the columnar supporters is embedded in the columnar supporters.
